(19) United States
(12) Patent Application Publication
(10) Pub. No.: US 2025/0328077 A1
(43) Pub. Date: Oct. 23, 2025

(54) METHOD OF CONTROLLING IMAGING CHARACTERISTICS IN FLEXOGRAPHIC RELIEF IMAGE PRINTING PLATES

(71) Applicant: MacDermid Graphics Solutions, LLC, Waterbury, CT (US)

(72) Inventors: Ryan W. Vest, Mequon, WI (US); Kyle P. Baldwin, Acworth, GA (US)

(21) Appl. No.: 19/060,894

(22) Filed: Feb. 24, 2025

Related U.S. Application Data
(60) Provisional application No. 63/636,917, filed on Apr. 22, 2024.

(51) Int. Cl. G03F 7/20

(52) U.S. Cl. CPC G03F 7/2004; G03F 7/202

(57) ABSTRACT

A method of controlling imaging characteristics of at least one relief printing feature created in a photosensitive printing blank during a platemaking process is provided. The photosensitive printing blank has a photocurable layer disposed on a backing layer. The photocurable layer is selectively exposed to a source of actinic radiation to selectively cross link and cure portions of the photocurable layer. The source of actinic radiation comprises one or more sets of UV LED lights that operate at different wavelength outputs and/or that are collimated to achieve different angles of UV light, and a power intensity of each individual UV LED light is individually adjusted and controlled. A relief image is revealed when the exposed photocurable layer is developed comprising at least one relief printing feature exhibiting geometric characteristics that provide for optimal printing performance.

### FIELD OF THE INVENTION

The present invention relates generally to a method of controlling image characteristics in flexographic relief image printing plates.

### BACKGROUND OF THE INVENTION

Flexography is a method of printing that is commonly used for high-volume runs. Flexography is employed for printing on a variety of substrates such as paper, paperboard stock, corrugated board, films, foils and laminates. Newspapers and grocery bags are prominent examples. Coarse surfaces and stretch films can be economically printed only by means of flexography.

Flexographic printing plates are relief plates with image elements raised above open areas. Generally, the plate is somewhat soft, and flexible enough to wrap around a printing cylinder, and durable enough to print over a million copies. Such plates offer a number of advantages to the printer, based chiefly on their durability and the ease with which they can be made. A typical flexographic printing plate as delivered by its manufacturer is a multilayered article made of in order, a backing or support layer; one or more unexposed photocurable layers; optionally a protective layer or slip film; and often, a protective cover sheet.

The support (or backing) layer lends support to the plate. The support layer can be formed from a transparent or opaque material such as paper, cellulose film, plastic, or metal. Preferred materials include sheets made from synthetic polymeric materials such as polyesters, polystyrene, polyolefins, polyamides, and the like. One widely used support layer is a flexible film of polyethylene terephthalate.

The photocurable layer(s) can include any of the known photopolymers, monomers, initiators, reactive or non-reactive diluents, fillers, and dyes. As used herein, the term “photocurable” refers to a composition which undergoes polymerization, cross-linking, or any other curing or hardening reaction in response to actinic radiation with the result that the unexposed portions of the material can be selectively separated and removed from the exposed (cured) portions to form a three-dimensional relief pattern of cured material. Exemplary photocurable materials are disclosed in European Patent Application Nos. 0 456 336 A2 and 0 640 878 A1 to Goss, et al., British Patent No. 1,366,769, U.S. Pat. No. 5,223,375 to Berrier, et al., U.S. Pat. No. 3,867,153 to MacLahan, U.S. Pat. No. 4,264,705 to Allen, U.S. Pat. Nos. 4,323,636, 4,323,637, 4,369,246, and 4,423,135 all to Chen, et al., U.S. Pat. No. 3,265,765 to Holden, et al., U.S. Pat. No. 4,320,188 to Heinz, et al., U.S. Pat. No. 4,427,759 to Gruetzmacher, et al., U.S. Pat. No. 4,622,088 to Min, and U.S. Pat. No. 5,135,827 to Bohm, et al., the subject matter of each of which is herein incorporated by reference in its entirety. More than one photocurable layer may also be used.

Photocurable materials generally cross-link (cure) and harden through radical polymerization in at least some actinic wavelength region. As used herein, “actinic radiation” is radiation that is capable of polymerizing, crosslinking or curing the photocurable layer. Actinic radiation includes, for example, amplified (e.g., laser) and non-amplified light, particularly in the UV and violet wavelength regions.

The slip film is a thin layer, which protects the photopolymer from dust and increases its ease of handling. In a conventional (“analog”) plate making process, the slip film is transparent to UV light, and the printer peels the cover sheet off the printing plate blank and places a negative on top of the slip film layer. The plate and negative are then subjected to flood-exposure by UV light through the negative. The areas exposed to the light cure, or harden, and the unexposed areas are removed (developed) to create the relief image on the printing plate.

In a “digital” or “direct to plate” process, a laser is guided by an image stored in an electronic data file, and is used to create an in situ negative in a digital (i.e., laser ablatable) masking layer, which is generally a slip film which has been modified to include a radiation opaque material. Portions of the laser ablatable layer are then ablated by exposing the masking layer to laser radiation at a selected wavelength and power of the laser. Examples of laser ablatable layers are disclosed, for example, in U.S. Pat. No. 5,925,500 to Yang, et al., and U.S. Pat. Nos. 5,262,275 and 6,238,837 to Fan, the subject matter of each of which is herein incorporated by reference in its entirety.

Processing steps for forming relief image printing elements typically include the following:
1) Image generation, which may be mask ablation for digital “computer to plate” printing plates or negative production for conventional analog plates;
2) Back exposure to create a floor layer in the photocurable layer and establish the depth of relief;
3) Face exposure through the mask (or negative) to selectively crosslink and cure portions of the photocurable layer not covered by the mask, thereby creating the relief image;
4) Development to remove unexposed photopolymer by solvent (including water) or thermal development; and
5) If necessary, post exposure and detackification.

Removable coversheets are also typically provided to protect the photocurable printing element from damage during transport and handling. Prior to processing the printing elements, the coversheet(s) are removed and the photosensitive surface is exposed to actinic radiation in an imagewise fashion. Upon imagewise exposure to actinic radiation, polymerization, and hence, insolubilization of the photopolymerizable layer occurs in the exposed areas. Treatment with a suitable developer solvent (or thermal development) removes the unexposed areas of the photopolymerizable layer, leaving a printing relief that can be used for flexographic printing.

As used herein “back exposure” refers to a blanket exposure to actinic radiation of the photopolymerizable layer on the side opposite that which does, or ultimately will, bear the relief. This step is typically accomplished through a transparent support layer and is used to create a shallow layer of photocured material, i.e., the “floor,” on the support side of the photocurable layer. The purpose of the floor is generally to sensitize the photocurable layer and to establish the depth of relief.

Following the brief back exposure step (i.e., brief as compared to the imagewise exposure step which follows), an imagewise exposure is performed utilizing a digitally-imaged mask or a photographic negative mask, which is in contact with the photocurable layer and through which actinic radiation is directed.

After imaging, the photosensitive printing element is developed to remove the unpolymerized portions of the layer of photocurable material and reveal the crosslinked relief image in the cured photosensitive printing element. Typical methods of development include washing with various solvents or water, often with a brush. Other possibilities for development include the use of an air knife or thermal development, which typically uses heat plus a blotting material. The resulting surface has a relief pattern, which typically comprises a plurality of dots that reproduces the image to be printed. After the relief image is developed, the resulting relief image printing element may be mounted on a press and printing commenced.

### SUMMARY OF THE INVENTION

It is an object of the present invention to provide an improved method of imagewise exposing a photosensitive relief image printing element to actinic radiation.

It is another object of the present invention to provide an improved method of imagewise exposing a photosensitive relief image printing element to actinic radiation using a UV LED light source.

It is still another object of the present invention to produce a relief image printing elements that includes at least one relief feature that exhibits an improved imaging characteristic including a superior geometric structure in terms of a desired planarity of a top surface of the at least one relief feature, a desired shoulder angle of the at least one relief feature and a desired edge sharpness of the at least one relief feature.

It is still another object of the present invention to improve imaging characteristics of a flexographic printing plate without also having to alter and/or change the composition of the photocurable layer.

To that end, the present invention relates generally to a method of controlling imaging characteristics of at least one relief printing feature created in a photosensitive printing blank during a platemaking process, said photosensitive printing blank comprising at least one photocurable layer disposed on a backing layer, the method comprising the steps of:
a. selectively exposing the at least one photocurable layer to a source of actinic radiation to selectively crosslink and cure the at least one photocurable layer; and
b. developing the exposed at least one photocurable layer of the photosensitive printing blank to reveal a relief image therein, said relief image comprising the at least one relief printing feature;
wherein the source of actinic radiation comprises an arrangement of UV LED lights, wherein the arrangement of UV LED lights comprises one or more sets of UV LED lights, UV LED tubes, or a combination thereof that operate at different wavelength outputs and/or that are collimated to achieve different angles of UV light, wherein a power intensity of each individual UV LED light or UV LED light tube is individually adjusted and controlled;
wherein the arrangement of UV LED lights produces at least one relief printing feature having at least one improved imaging characteristic, wherein the at least one improved imaging characteristic comprises at least one geometric characteristic selected from the group consisting of a desired planarity of a top surface of the at least one relief printing feature, a desired shoulder angle of the at least one relief printing feature, and a desired edge sharpness of the at least one relief printing feature.

### BRIEF DESCRIPTION OF THE FIGURES

For a fuller understanding of the invention, reference is had to the following description taken in connection with the accompanying figure, in which:

FIG. 1 depicts the measurement of the relief printing feature shoulder angle θ.

### DETAILED DESCRIPTION OF THE PREFERRED EMBODIMENTS

The type of radiation used for exposing a photocurable printing blank to actinic radiation is dependent in part on the type of photoinitiator used in the photopolymerizable layer. The digitally-imaged mask or photographic negative prevents the material beneath from being exposed to the actinic radiation and hence those areas covered by the mask do not polymerize, while the areas not covered by the mask are exposed to actinic radiation and polymerize, creating the relief image. Any conventional sources of actinic radiation can be used for this exposure step. Examples of suitable visible and UV sources include carbon arcs, mercury-vapor arcs, fluorescent lamps, electron flash units, electron beam units and photographic flood lamps.

The shape of the dots and the depth of the relief, among other factors, affect the quality of the relief image. In addition, it is very difficult to print small graphic elements such as fine dots, lines and even text using flexographic printing plates while maintaining open reverse text and shadows. In the lightest areas of the image (commonly referred to as highlights) the density of the image is represented by the total area of dots in a halftone screen representation of a continuous tone image. For Amplitude Modulated (AM) screening, this involves shrinking a plurality of halftone dots located on a fixed periodic grid to a very small size, the density of the highlight being represented by the area of the dots. For Frequency Modulated (FM) screening, the size of the halftone dots is generally maintained at some fixed value, and the number of randomly or pseudo-randomly placed dots represent the density of the image. In both cases, it is necessary to print very small dot sizes to adequately represent the highlight areas.

Maintaining small dots on flexographic plates can be very difficult due to the nature of the platemaking process. In digital platemaking processes that use a UV-opaque mask layer, the combination of the mask and UV exposure produces relief dots that have a generally conical shape. The smallest of these dots are prone to being removed during processing, which means no ink is transferred to these areas during printing (i.e., the dot is not “held” on plate and/or on press). Alternatively, if the dots survive processing, they are susceptible to damage on press. For example, small dots often fold over and/or partially break off during printing, causing either excess ink or no ink to be transferred.

As described in U.S. Pat. No. 8,158,331 to Recchia and U.S. Pat. Pub. No. 2011/0079158 to Recchia et al., the subject matter of each of which is herein incorporated by reference in its entirety, it has been found that a particular set of geometric characteristics define a flexographic dot shape that can yield superior printing performance in certain situations, including, but not limited to, (1) planarity of the dot surface; (2) shoulder angle of the dot; (3) depth of relief between the dots; and (4) sharpness of the edge at the point where the dot top transitions to the dot shoulder.

LED lights may be used for crosslinking and curing photosensitive and/or photocurable layers in relief image printing elements. However, many earlier generations of LED lights were only capable of emitting UV light at a prescribed measured intensity at the surface of the flexographic printing plate that was inadequate to improve geometric characteristics of flexographic printing features (i.e., relief printing dots and/or relief printing lines) for flexographic printing. It has therefore been a struggle to avoid excessive broadening at the surface of the relief printing dots and/or relief printing lines, which can lead to a poor result.

During the exposure step, the photosensitive printing blank may be brought into contact with an imaging system, i.e., an exposure unit comprising UV LED lights, which selectively exposes the photocurable layer of the photosensitive printing blank to a source of actinic radiation, i.e., UV light to crosslink and cure at least portions of the photocurable layer. This exposure unit simply cures the photosensitive printing blank. That is, the imaging device emits UV light in a range or at a specific wavelength and at pre-set intensities and there is no ability to adjust and/or alter intensities or to utilize different wavelengths at specific intensities. Therefore, there is no ability to adjust and/or control imaging characteristics with these devices. Without the ability to change and/or adjust the device settings, the only way to improve imaging characteristics of the photosensitive printing blank is to create different formulations of the photocurable layer(s) to achieve a better result.

The ability to control and/or tailor various imaging characteristics of the relief image printing plate in a UV LED imaging system largely depends on the particular chemical formulation of the photocurable layer. Since each printing job is unique, this can be problematic from a cost, efficiency, and performance perspective.

In addition, it can take a considerable amount of time to determine optimal flexographic printing settings (i.e., chemical composition(s) and wavelength output(s)) for a specific flexographic printing job based on the current UV LED systems.

The inventors of the present invention have found that the use of one or more sets of UV LED lights that operate at different wavelength outputs and/or that are collimated to achieve different angles of UV light and that the power intensities of the one or more sets of UV LED lights are individually adjustable and controllable, to selectively cross-link and cure at least one photocurable layer, can produce a relief image comprising flexographic printing features (i.e., relief printing features) having improved imaging characteristics.

It should be understood that the disclosed embodiments are merely illustrative of the present disclosure, which may be embodied in various forms.

As used herein, “a,” “an,” and “the” refer to both singular and plural referents unless the context clearly dictates otherwise.

As used herein, the term “about” refers to a measurable value such as a parameter, an amount, a temporal duration, and the like and is meant to include variations of +/−15% or less, preferably variations of +/−10% or less, more preferably variations of +/−5% or less, even more preferably variations of +/−1% or less, and still more preferably variations of +/−0.1% or less of and from the particularly recited value, in so far as such variations are appropriate to perform in the invention described herein. Furthermore, it is also to be understood that the value to which the modifier “about” refers is itself specifically disclosed herein.

As used herein, spatially relative terms, such as “beneath”, “below”, “lower”, “above”, “upper”, “front”, “back”, and the like, are used for ease of description to describe one element or feature's relationship to another element(s) or feature(s). It is further understood that the terms “front” and “back” are not intended to be limiting and are intended to be interchangeable where appropriate.

As used herein, the terms “comprise(s)” and/or “comprising,” specify the presence of stated features, integers, steps, operations, elements, and/or components, but do not preclude the presence or addition of one or more other features, integers, steps, operations, elements, components, and/or groups thereof.

As defined herein, the term “power intensity” refers to an output intensity of an individual UV LED light, as measured in mW.

As defined herein, the term “measured intensity at the surface” refers to the quantity of UV light at a working surface, i.e., the surface of the flexographic printing plate, as measured in mW/cm².

As described herein, a problem with prior art UV LED lights is that they could not emit UV light at a measured intensity at the surface of the flexographic printing plate that was capable of achieving optimal imaging characteristics, including, for example, a desired planarity of a top surface of the at least one relief printing feature, a desired shoulder angle of the at least one relief printing feature, and a desired edge sharpness of the at least one relief printing feature contained in a flexographic relief image printing element. That is, in prior art UV LED systems, the ability to control geometric characteristics of printing features in a relief image printing element was limited to either tailoring the chemical composition of photocurable printing layers(s) including the selection of an optimal photoinitiator or by selecting UV LED lights that could operate at a desired wavelength output(s) and it was not possible to individually adjust and/or control the power intensity and/or the wavelength outputs of the UV LED lights or each individual UV LED light in order to improve the imaging characteristics. As described in U.S. Pat. No. 9,046,778 to Baldwin, the subject matter of which is herein incorporated by reference in its entirety, it has been found that the geometric characteristics that define relief printing features can be influenced by the particular chemical formulation of the photocurable polymer layer as well as the specific design of the UV light assembly.

The inventors of the present invention have now discovered that UV LED lights in an arrangement or an array of UV LED lights can be individually controlled with respect to their power intensity to produce an optimal measured intensity at the surface of the relief image printing element that results in optimal and imaging characteristics and therefore improved printing features being formed in a photocurable printing layer of a relief image printing element. That is, these improved UV LED lights can emit UV light at the necessary power intensity, and this power intensity can be adjusted and controlled to provide improved geometric characteristics. In addition, the use of the UV LED light arrangement described herein can produce an optimal result in terms of one or more of a desired planarity of a top surface of the at least one relief printing feature, a desired shoulder angle of the at least one relief printing feature, and a desired edge sharpness of the at least one relief printing feature that is not directly tied to the photocurable composition, allowing for the use of the UV LED light arrangement to crosslink and cure a variety of photocurable compositions containing different combinations of photopolymers, monomers, initiators, reactive or non-reactive diluents, fillers, dyes, and other components in an efficient manner.

The inventors of the present invention have found that the use of one or more sets of UV LED lights that operate at different wavelength outputs and/or that are collimated to achieve different angles of UV light and that the power intensities of the two or more sets of UV LED lights are individually adjustable and controllable, to selectively cross-link and cure at least one photocurable layer, can produce a relief image comprising flexographic printing features (i.e., relief printing features) having improved imaging characteristics.

Additionally, the inventors of the present invention have found that the optimal flexographic printing settings, i.e., power intensity and wavelength output(s), can be efficiently determined for a specific print job by individually adjusting and controlling the power intensity of each the UV LED lights. The inventors of the present invention have also found that the geometric characteristics of flexographic printing features can be more efficiently optimized by altering the power intensity. These advantages/improvements help to reduce the overall costs of the flexographic printing process.

In one embodiment, the present invention relates generally to a method of controlling imaging characteristics of at least one relief printing feature created in a photosensitive printing blank during a platemaking process, said photosensitive printing blank comprising at least one photocurable layer disposed on a backing layer, the method comprising the steps of:
a. selectively exposing the at least one photocurable layer to a source of actinic radiation to selectively crosslink and cure the at least one photocurable layer; and
b. developing the exposed at least one photocurable layer of the photosensitive printing blank to reveal a relief image therein, said relief image comprising the at least one relief printing feature;
wherein the source of actinic radiation comprises an arrangement of UV LED lights, wherein the arrangement of UV LED lights comprises one or more sets of UV LED lights, UV LED tubes, or a combination thereof that operate at different wavelength outputs and/or that are collimated to achieve different angles of UV light, wherein a power intensity of each UV LED light or UV LED light tube is individually adjusted and controlled;
wherein the arrangement of UV LED lights produces at least one relief printing feature having at least one improved imaging characteristic, wherein the at least one improved imaging characteristic comprises at least one geometric characteristic selected from the group consisting of a desired planarity of a top surface of the at least one relief printing feature, a desired shoulder angle of the at least one relief printing feature, and a desired edge sharpness of the at least one relief printing feature.

The shape and structure of the at least one relief printing feature significantly impacts the printing performance of the photosensitive printing blank. The at least one relief printing feature can be selected from the list including at least one or more relief printing dots, one or more relief printing lines, or a combination thereof.

The method described herein can be used for producing relief image printing elements in both a liquid photopolymer platemaking process as well as a sheet polymer platemaking process.

In one embodiment, the arrangement of UV LED lights comprises UV LED lights that operate at different wavelength outputs and/or that are collimated to achieve different degrees of UV light collimation. In another embodiment, the arrangement of UV LED lights comprises UV LED lights that operate at two different wavelength outputs or even three different wavelength outputs and/or that are collimated to achieve two or more or more or even three or more different degrees of UV light collimation.

It should also be understood that UV light can be emitted over a range of wavelength outputs, often referred to as the Spectral Energy Distribution, with a peak at one wavelength output which is the identified wavelength output. Typical UV light source emission wavelength outputs range from 100 nm to 400 nm and the wavelength of visible light ranges from 400 nm to 700 nm. The different wavelength outputs are available in wavelengths of 365 nm, 375 nm, 385 nm, 395 nm, 405 nm, among others.

In one embodiment, the arrangement of UV LED lights comprises UV LED lights that operate at a first wavelength output in a range of about 355 nm to about 375 nm, preferably about 365 nm, that are individually adjustable to a power intensity for the lower wavelength output, and UV LED lights that operate at a second wavelength output in a range of about 395 nm, and UV LED lights that operate at a third wavelength output in a range of about 405 nm, that are individually adjustable to a power intensity for the higher wavelength output.

In another embodiment, the arrangement of UV LED lights comprises UV LED lights that operate at a lower wavelength output in a range of about 355 nm to about 375 nm, preferably about 365 nm, that are individually adjustable to a power intensity for the lower wavelength output, and UV LED lights that operate at a higher wavelength output in a range of about 385 nm to about 405 nm, preferably about 395 nm, that are individually adjustable to a power intensity for the higher wavelength output. In one embodiment, a combination of the UV LED lights that operate at a lower wavelength output and the UV LED lights that operate at a higher wavelength output is used in a two-step process. In such a process, the at least one photocurable layer is exposed to either the UV LED lights that operate at the lower wavelength output or the UV LED lights that operate at the higher wavelength output and then sequentially is exposed to the other of the UV LED lights that operate at the lower wavelength output or the UV LED lights that operate at the higher wavelength output. In another embodiment, a combination of the UV LED lights that operate at the lower wavelength output and the UV LED lights that operate at the higher wavelength output are used simultaneously to cross-link and cure the at least one photocurable layer.

The arrangement of UV LED lights comprises one or more sets of UV LED lights, UV LED tubes, or a combination thereof. The one or more sets of UV LED lights can be arranged in a plurality of rows or in an array. The UV LED lights in the array can have a variety of different shapes and/or sizes (to include tubes) and can be placed in various proximities to each other to customize the geometric characteristics of the at least one relief printing feature. The one or more sets of UV LED lights can also comprise UV LED light tubes that are placed lengthwise, adjacent to one another, and can also be placed in various proximities to each other to customize the geometric characteristics of the at least one relief printing feature. The number of UV LED light tubes is not limited but typically ranges from about 3 to about 5. It is understood that UV LED light tubes are linear tubular shaped bulbs that range in length from about 1 foot to about 8 feet and have a diameter from about 0.50 inches to about 1.5 inches.

The one of more sets of UV LED lights can also be positioned in a random, mixed manner or in sequential rows. For example, in a preferred embodiment, the one or more sets of UV LED lights comprise rows of UV LED lights, wherein alternating rows of UV LED lights operate at different wavelength outputs (i.e., about 365 nm and about 395 nm wavelength outputs). In another preferred embodiment, the one or more sets of UV LED lights comprise rows of UV LED lights, wherein a first row comprises a UV LED light operating at a first wavelength output disposed adjacent to another UV LED light operating at a second wavelength output, repeating this pattern throughout the row. The next row and subsequent rows can have the same pattern or a different pattern.

In another embodiment, each of the UV LED lights in the arrangement of UV LED lights is individually controlled to produce a power intensity for each UV LED light in the arrangement of UV LED lights. The power intensity of each individual UV LED light or UV LED light tube is individually adjusted and controlled either manually or automatically. In one non-limiting embodiment, each individual UV LED light or UV LED light tube is placed on a separate circuit and the resistor value of each circuit is adjusted (i.e., by a potentiometer). In another embodiment, each individual UV LED light or UV LED light tube is independently activated and de-activated at a high frequency while changing the percentage a particular UV LED light or UV LED light tube is activated versus de-activated using pulse width modulation.

In one embodiment, the power intensity of each UV LED light in the arrangement of UV LED lights operating at the lower wavelength output is in a range of about 15 mW to about 40 mW, more preferably in a range of about 20 mW to about 35 mW, most preferably in a range of about 25 mW to about 35 mW and the power intensity of each UV LED light in the arrangement of UV LED lights operating at the higher wavelength output is in a range of about 15 mW to about 40 mW, more preferably in a range of about 20 mW to about 35 mW, most preferably in a range of about 25 mW to about 35 mW.

This power intensity is capable of achieving a measured intensity at the surface of the photosensitive printing blank from each of the UV LED lights in the arrangement of UV LED lights that is at least about 10 mW/cm², preferably at least about 25 mW/cm², more preferably at least about 35 mW/cm², even more preferably at least about 50 mW/cm², or at least about 75 mW/cm² when the arrangement of the UV LED lights is positioned at a distance of between about 1 cm and about 10 cm, preferably about 3 cm to about 6 cm, from the surface of the photosensitive printing blank.

In one embodiment, the power intensity emanating from each UV LED light in the arrangement of UV LED lights ranges from about 25 mW to about 30 mW to achieve the required measured intensity at the surface of the photosensitive printing blank.

The UV light is emitted from the arrangement of UV LED lights at different angles, as measured as the light impacts the at least one photocurable layer. However, after being collimated, the light rays of the UV light travel in parallel and ideally do not diverge over a distance. In non-limiting examples, the desired degree of collimation can be achieved through the use of lenses, mirrors, and/or by placing a collimating grid above the photosensitive printing blank during the exposure step, as described in U.S. Pat. No. 6,245,487 to Randall, the subject matter of which is herein incorporated by reference in its entirety.

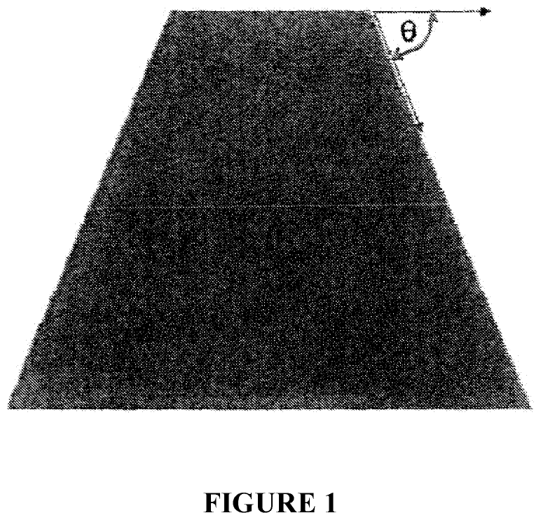

As used herein, “relief printing feature shoulder angle” simply means the angle formed by the intersection of a horizontal line tangential to the top of the relief printing feature and a line representing the adjacent relief printing feature side wall, represented by angle θ in FIG. 1. At the extreme, a relief printing feature has an angle θ of 90°, similar to a vertical column. However, in practice, most relief printing features have a relief printing feature shoulder angle that is considerably lower.

The inventors have found that an angle θ of between about 80° and about 90°, i.e., a very sharp relief printing feature shoulder angle, is typically produced by using UV LED lights that are highly collimated and have a lower wavelength output (i.e., about 365 nm). The inventors have also found that an angle θ of about 30° or less, i.e., a relief printing feature having a broad surface, is typically produced using UV LED lights having a higher wavelength output such as at about 395 nm, regardless of whether the UV LED lights are collimated or non-collimated. The inventors have found that the angle θ can be adjusted and/or controlled using a combination of UV LED lights, operating at a lower wavelength output and operating at a higher wavelength output, to improve the imaging characteristics of the flexographic printing plate. By using a combination of UV LED lights operating at different wavelengths, the angle θ can be adjusted and/or controlled to fit the needs of the customer. For example, the angle θ can be adjusted and/or controlled to within range of about 40° to about 80°, preferably about 45° to about 60° or any other angle θ that may fit the needs of the customer for a particular printing run.

In one embodiment, at least a portion of the UV LED lights are collimated, optionally wherein about 10% to about 90% or about 20% to about 80% or about 30% to about 70% or about 40% to about 60% or about 45% to about 55% of the UV LED lights are collimated and the remaining UV LED lights are not collimated. In another embodiment, the UV LED lights that operate at the lower wavelength output has at least a portion of the UV LED lights that are collimated. In an alternative embodiment, the UV LED lights that operate at the higher wavelength output has at least a portion of the UV LED lights that are collimated.

In yet another embodiment, at least a portion of the UV LED lights are collimated and at least a portion of the UV LED lights are not collimated, wherein UV LED lights operate at the same wavelength output, preferably in the range from about 355 nm to about 405 nm, more preferably at about 365 nm. In another embodiment, the wavelength output of the collimated UV LED lights is in the range of about 355 nm to about 375 nm, more preferably about 365 nm, or the wavelength output of the non-collimated UV LED lights is in the range of about 385 nm to about 405 nm, more preferably about 395 nm. In yet embodiment, the UV LED lights are arranged in rows, and alternate rows of UV LED lights comprise collimated UV LED lights and non-collimated UV LED lights.

All of these methods have been found to optimize the angle θ of the printing relief feature so that such an angle can be adjusted and/or controlled to achieve a desired result.

The at least one photocurable layer may comprise any of the known photopolymers, monomers, initiators, reactive or non-reactive diluents, fillers, dyes, additives, and other components known to those skilled in the art. In one embodiment, the at least one photocurable layer comprises at least one photoinitiator that has a UV-Vis absorption peak that is near or in the range of an operating wavelength output of the UV LED lights.

One non-limiting example of a suitable photoinitiator having a UV-Vis absorption peak around the lower wavelength output is 2,2-dimethyoxy-1,2-di(phenyl) ethanone available from Ciba Specialty Chemicals, Inc. under the tradename Irgacure 651. Other photoinitiators can also be used that have a similar UV-Vis absorption peak around the lower wavelength output.

In another embodiment, the at least one photocurable layer comprises at least one additive capable of altering the curing behaviour of the at least one photocurable layer selected from the list comprising UV absorbers, radical scavengers, Type II initiators, and combinations thereof and the at least one additive may be used alone or in combination with the photoinitiators described herein. In another embodiment, the at least one additive has a UV-Vis absorption peak that is near or in the range of an operating wavelength output of the UV LED lights.

Examples of commercially available types of photoinitiators that initiate at the higher wavelength output are mono acyl phosphine (MAPO) and bis acyl phosphine (BAPO). MAPO photoinitiators include diphenyl(2,4,6-trimethylbenzoyl)-phosphine oxide, available commercially from BASF under the tradename Darocur TPO. BAPO photoinitiators include phenyl bis(2,4,6-trimethyl benzoyl) phosphine oxide, available commercially from BASF under the tradename Irgacure 819. MAPO's absorption peaks are at 295 nm, 368 nm, 380 nm and 393 nm. BAPO's absorption peaks are at 295 nm and 370 nm. Other photoinitiators that are advertised to initiate at the higher wavelength output include Bis(eta 5-2,4-cyclopentadien-1-yl)Bis [2,6-difluoro-3-) 1H-pyrrol-1-yl)phenyl]titanium, which is a metallocene that is commercially available from BASF under the tradename Irgacure 784 and which has absorption peaks at 398 and 470. Preferred photoinitiators that initiate at the higher wavelength output include diphenyl(2,4,6-trimethylbenzoyl)-phosphine oxide, available commercially from BASF under the tradename Darocur TPO and 2-benzyl-2-(dimethylamino)-1-[4-(4-morpholinyl)-1-propanone, available from Ciba Specialty Chemicals, Inc, under the tradename Irgacure 369.

In one embodiment, a custom array of UV LED lights or a custom arrangement of UV LED light tubes can be used. In another embodiment, the arrangement of UV LED lights is such that individual UV LED lights operating at different wavelengths and/or different power intensities and/or different levels of collimation are arranged in the arrangement of UV LED lights in a random manner. In another embodiment, the arrangement of UV LED lights is such that the individual UV LED lights operating at different wavelengths and/or different power intensities and/or different levels of collimation are arranged in the arrangement of UV LED lights in an alternating manner. In another embodiment, individual UV LED lights operating at different wavelengths and/or different power intensities and/or different levels of collimation are arranged in the arrangement of UV LED lights in rows, in which one or more rows of UV LED lights may be the same or different from each other.

Finally, it should also be understood that the following claims are intended to cover all of the generic and specific features of the invention described herein and all statements of the scope of the invention that, as a matter of language might fall therebetween.

### Additional Embodiments

Clause 1: A method of controlling imaging characteristics of at least one relief printing feature created in a photosensitive printing blank during a platemaking process, said photosensitive printing blank comprising at least one photocurable layer disposed on a backing layer, the method comprising the steps of:
a. selectively exposing the at least one photocurable layer to a source of actinic radiation to selectively crosslink and cure the at least one photocurable layer; and
b. developing the exposed at least one photocurable layer of the photosensitive printing blank to reveal a relief image therein, said relief image comprising the at least one relief printing feature;
   wherein the source of actinic radiation comprises an arrangement of UV LED lights, wherein the arrangement of UV LED lights comprises one or more sets of UV LED lights, UV LED tubes, or a combination thereof that operate at different wavelength outputs and/or that are collimated to achieve different angles of UV light, wherein a power intensity of each individual UV LED light or UV LED light tube is individually adjusted and controlled;
   wherein the arrangement of UV LED lights produces at least one relief printing feature having at least one improved imaging characteristic, wherein the at least one improved imaging characteristic comprises at least one geometric characteristic selected from the group consisting of a desired planarity of a top surface of the at least one relief printing feature, a desired shoulder angle of the at least one relief printing feature, and a desired edge sharpness of the at least one relief printing feature.

Clause 2: the method of Clause 1, wherein the arrangement of UV LED lights comprises UV LED lights that operate at a lower wavelength output in a range of about 355 to about 375 nm and that are individually adjustable to a power intensity for the lower wavelength output and UV LED lights that operate at a higher wavelength output in a range of about 385 to about 405 nm and that are individually adjustable to a power intensity for the higher wavelength output.

Clause 3: the method of Clause 1 or Clause 2, wherein each of the UV LED lights in the arrangement of UV LED lights is individually controlled to produce a power intensity for each UV LED light in the arrangement of UV LED lights.

Clause 4: the method of any of Clauses 1 to 3, wherein the lower wavelength output is about 365 nm and the higher wavelength output is about 395 nm.

Clause 5: the method of any of Clauses 1 to 4, wherein the power intensity of each of the UV LED lights operating at the lower wavelength output is in a range of about 15 mW to about 40 mW, more preferably in a range of about 20 mW to about 35 mW, most preferably in a range of about 25 mW to about 35 mW and the power intensity of each UV LED light in the arrangement of UV LED lights operating at the higher wavelength output is in a range of about 15 mW to about 40 mW, more preferably in a range of about 20 mW to about 35 mW, most preferably in a range of about 25 mW to about 35 mW.

Clause 6: the method of any of Clauses 1 to 5, wherein the at least one relief printing feature comprise at least one of one or more relief printing dots and one or more relief printing lines.

Clause 7: the method of any of Clauses 1 to 6, wherein the at least one photocurable layer comprises at least one photoinitiator, wherein said at least one photoinitiator has a UV-Vis absorption peak in the range of an operating wavelength of the UV LED lights.

Clause 8: the method of any of Clauses 1 to 7, wherein the improved imaging characteristics are achieved in the photocurable printing blank even if the composition of the at least one photocurable layer is altered or changed or if a different photoinitiator is used.

Clause 9: the method of any of Clauses 1 to 8, wherein the improved imaging characteristics achieved in the photocurable printing blank do not depend on the composition of the at least one photocurable layer.

Clause 10: the method of any of Clauses 1 to 9, wherein the one or more sets of UV LED lights comprise UV LED light tubes.

Clause 11: the method of any of Clauses 1 to 10, wherein the one or more sets of UV LED lights are arranged in at least one row or an array.

Clause 12: the method of any of Clauses 1 to 11, wherein the one or more sets of UV LED lights comprise rows of UV LED lights, wherein alternating rows of UV LED lights operate at different wavelength outputs.

Clause 13: the method of Clause 1, wherein the arrangement of UV LED lights comprises UV LED lights arranged to have different angles of light, wherein at least a portion of the UV LED lights are collimated, optionally wherein about 10% to about 90% or about 20% to about 80% or about 30% to about 70% or about 40% to about 60% or about 45% to about 55% of the UV LED lights are collimated and the remaining UV LED lights are not collimated, wherein the UV LED lights operate at a same wavelength output.

Clause 14: the method of Clause 13, wherein the same wavelength output ranges from about 355 nm to about 405 nm, more preferably about 365 nm.

Clause 15: the method of Clause 13 or Clause 14, wherein the UV LED lights are arranged in rows, and alternate rows of UV LED lights comprise collimated UV LED lights and non-collimated UV LED lights.

Clause 16: the method of Clause 13, wherein the wavelength output of the collimated UV LED lights is in the range of about 355 nm to about 375 nm, more preferably about 365 nm or the wavelength output of the non-collimated UV LED lights is in the range of about 385 nm to about 405 nm, more preferably about 395 nm.

Clause 17: the method of Clause 1, wherein a measured intensity at the surface of the photosensitive printing blank from each of the UV LED lights in the arrangement of UV LED lights is at least about 10 mW/cm², preferably at least about 25 mW/cm², more preferably at least about 35 mW/cm², even more preferably at least about 50 mW/cm², more preferably at least about 75 mW/cm² when the arrangement of UV LED lights is positioned at a distance of between 1 cm and 10 cm from the surface of the photosensitive printing blank.

Clause 18: the method of Clause 17, wherein the power intensity emanating from each UV LED light in the arrangement of UV LED lights ranges from about 25 mW to about 30 mW.

Clause 19: the method of Clause 17 or Clause 18, wherein the at least one geometric characteristic comprises the desired shoulder angle of the at least one printing feature.

Clause 20: the method of any of Clauses 1 to 19, wherein the distance between the arrangement of UV LED lights and the surface of the photosensitive printing blank is between about 1 cm and about 10 cm, more preferably from about 3 cm to about 6 cm.

Clause 21: the method of Clause 1, wherein the array of UV LED lights or the set of UV LED tube bulbs comprises alternating rows of about 365 nm and about 395 nm wavelength outputs.

Clause 22: the method of Clause 1, wherein the arrangement of UV LED lights comprises UV LED lights that operate at three or more different wavelength outputs and/or that are three or more different degrees of UV light collimation.

Clause 23: the method of Clause 2, wherein the UV LED lights that operate at the lower wavelength output have different angles of light, wherein at least a portion of the UV LED lights that operate at the lower wavelength output are collimated, wherein about 10% to about 90% or about 20% to about 80% or about 30% to about 70% or about 40% to about 60% or about 45% to about 55% of the UV LED lights that operate at the lower wavelength output are collimated and the remaining UV LED lights that operate at the lower wavelength output are not collimated.

Clause 24: the method of clause 2, wherein the UV LED lights that operate at the higher wavelength output have different angles of light, wherein at least a portion of the UV LED lights that operate at the higher wavelength output are collimated, wherein about 10% to about 90% or about 20% to about 80% or about 30% to about 70% or about 40% to about 60% or about 45% to about 55% of the UV LED lights that operate at the higher wavelength output are collimated and the remaining UV LED lights that operate at the higher wavelength output are not collimated.

1. A method of controlling imaging characteristics of at least one relief printing feature created in a photosensitive printing blank during a platemaking process, said photosensitive printing blank comprising at least one photocurable layer disposed on a backing layer, the method comprising the steps of:
a. selectively exposing the at least one photocurable layer to a source of actinic radiation to selectively crosslink and cure the at least one photocurable layer; and
b. developing the exposed at least one photocurable layer of the photosensitive printing blank to reveal a relief image therein, said relief image comprising the at least one relief printing feature;
wherein the source of actinic radiation comprises an arrangement of UV LED lights,
wherein the arrangement of UV LED lights comprises one or more sets of UV LED lights, UV LED tubes, or a combination thereof that operate at different wavelength outputs and/or that are collimated to achieve different angles of UV light, wherein a power intensity of each individual UV LED light or UV LED light tube is individually adjusted and controlled;
wherein the arrangement of UV LED lights produces at least one relief printing feature having at least one improved imaging characteristic, wherein the at least one improved imaging characteristic comprises at least one geometric characteristic selected from the group consisting of a desired planarity of a top surface of the at least one relief printing feature, a desired shoulder angle of the at least one relief printing feature, and a desired edge sharpness of the at least one relief printing feature.

2. The method of claim 1, wherein the arrangement of UV LED lights comprises UV LED lights that operate at a lower wavelength output in a range of about 355 to about 375 nm and that are individually adjustable to a power intensity for the lower wavelength output and UV LED lights that operate at a higher wavelength output in a range of about 385 to about 405 nm and that are individually adjustable to a power intensity for the higher wavelength output

3. The method of claim 2, wherein each of the UV LED lights in the arrangement of UV LED lights is individually controlled to produce a power intensity for each UV LED light in the arrangement of UV LED lights.

4. The method of claim 2, wherein the lower wavelength output is about 365 nm and the higher wavelength output is about 395 nm.

5. The method of claim 2, wherein the power intensity of each of the UV LED lights operating at the lower wavelength output is in a range of about 15 mW to about 40 mW and the power intensity of each UV LED light in the arrangement of UV LED lights operating at the higher wavelength output is in a range of about 15 mW to about 40 mW.

6. The method of claim 1, wherein the at least one relief printing feature comprise at least one of one or more relief printing dots and one or more relief printing lines.

7. The method of claim 1, wherein the at least one photocurable layer comprises at least one photoinitiator, wherein said at least one photoinitiator has a UV-Vis absorption peak in the range of an operating wavelength of the UV LED lights.

8. The method of claim 7, wherein the improved imaging characteristics are achieved in the photocurable printing blank even if the composition of the at least one photocurable layer is altered or changed or if a different photoinitiator is used.

9. The method of claim 1, wherein the improved imaging characteristics achieved in the photocurable printing blank do not depend on the composition of the at least one photocurable layer.

10. The method of claim 1, wherein the one or more sets of UV LED lights comprise UV LED light tubes.

11. The method of claim 1, wherein the one or more sets of UV LED lights are arranged in at least one row or an array.

12. The method of claim 1, wherein the one or more sets of UV LED lights comprise rows of UV LED lights, wherein alternating rows of UV LED lights operate at different wavelength outputs.

13. The method of claim 1, wherein the arrangement of UV LED lights comprises UV LED lights arranged to have different angles of light, wherein at least a portion of the UV LED lights are collimated, optionally wherein about 10% to about 90% or about 20% to about 80% or about 30% to about 70% or about 40% to about 60% or about 45% to about 55% of the UV LED lights are collimated and the remaining UV LED lights are not collimated, wherein the UV LED lights operate at a same wavelength output.

14. The method of claim 13, wherein the same wavelength output ranges from about 355 nm to about 405 nm.

15. The method of claim 13, wherein the UV LED lights are arranged in rows, and alternate rows of UV LED lights comprise collimated UV LED lights and non-collimated UV LED lights.

16. The method of claim 13, wherein the wavelength output of the collimated UV LED lights is in the range of about 355 nm to about 375 nm and the wavelength output of the non-collimated UV LED lights is in the range of about 385 nm to about 405 nm.

17. The method of claim 1, wherein a measured intensity at the surface of the photosensitive printing blank from each of the UV LED lights in the arrangement of UV LED lights is at least about 10 mW/cm² when the arrangement of UV LED lights is positioned at a distance of between 1 cm and 10 cm from the surface of the photosensitive printing blank.

18. The method of claim 17, wherein the power intensity emanating from each UV LED light in the arrangement of UV LED lights ranges from about 25 mW to about 30 mW.

19. The method of claim 1, wherein the at least one geometric characteristic comprises the desired shoulder angle of the at least one printing feature.

20. The method of claim 1, wherein the distance between the arrangement of UV LED lights and the surface of the photosensitive printing blank is between about 1 cm and about 10 cm.

21. The method of claim 11, wherein the array of UV LED lights or the set of UV LED tube bulbs comprises alternating rows of about 365 nm and about 395 nm wavelength outputs.

22. The method of claim 1, wherein the arrangement of UV LED lights comprises UV LED lights that operate at three or more different wavelength outputs and/or that are three or more different degrees of UV light collimation.

23. The method of claim 2, wherein the UV LED lights that operate at the lower wavelength output have different angles of light, wherein at least a portion of the UV LED lights that operate at the lower wavelength output are collimated, wherein about 10% to about 90% or about 20% to about 80% or about 30% to about 70% or about 40% to about 60% or about 45% to about 55% of the UV LED lights that operate at the lower wavelength output are collimated and the remaining UV LED lights that operate at the lower wavelength output are not collimated.

24. The method of claim 2, wherein the UV LED lights that operate at the higher wavelength output have different angles of light, wherein at least a portion of the UV LED lights that operate at the higher wavelength output are collimated, wherein about 10% to about 90% or about 20% to about 80% or about 30% to about 70% or about 40% to about 60% or about 45% to about 55% of the UV LED lights that operate at the higher wavelength output are collimated and the remaining UV LED lights that operate at the higher wavelength output are not collimated.
